(19) United States
(12) Patent Application Publication
(10) Pub. No.: US 2005/0264436 A1
(43) Pub. Date: Dec. 1, 2005

(54) Information processing apparatus

(75) Inventors: Kouichi Yamamoto, Musashimurayama (JP); Takashi Satou, Hitachinaka (JP); Toshimasa Kawamura, Hitachinaka (JP); Atsuo Souma, Hitachinaka (JP); Takashi Aizawa, Hino (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hitachi, Ltd., Tokyo (JP)

(21) Appl. No.: 10/892,938

(22) Filed: Jul. 16, 2004

(30) Foreign Application Priority Data
Apr. 21, 2004 (JP) 2004-125344

(51) Int. Cl. H03M 7/00

(52) U.S. Cl. 341/50

(57) ABSTRACT

A sliding type portable telephone has: a first operation unit for receiving input operations from the user while the open/close unit is in a contracted state; a second operation unit for receiving input operations from the user while the open/close unit is in an extended state; and a control unit for performing processing in response to the input operations that the operation units and received from the user. When the extended state is detected after processing is performed that responds to the first input operation received from the user via the first operation unit while in the contracted state, the control unit performs processing that responds to a second input operation, which can be a next input operation, before receiving the input operation subsequent to the first input operation from the user via the second operation unit.

### INCORPORATION BY REFERENCE

The present application claims priority from Japanese application JP2004-125344 filed on Apr. 21, 2004, the content of which is hereby incorporated by reference into this application.

### TECHNICAL FIELD

The present invention relates to an information processing apparatus having an open/close unit.

### BACKGROUND

Conventionally, various kinds of information processing apparatuses that have the open/close unit have been known as the information processing apparatus. They include, for example, a notebook personal computer, and a portable telephone. A known open/close mode of the portable telephone includes, for example, a folding, or a sliding type. A sliding type portable telephone is disclosed in, for example, Japanese Patent Application Laid-open No. (JP-A-2003-204383). The sliding type portable telephone comprises a main housing, and a movable housing which is engaged to the main housing slidably in a direction of the major axis of the main housing, wherein the telephone is opened or closed by sliding the movable housing as the open/close unit.

Some openable and closable portable telephones can receive certain input operations from a user regardless whether the open/close unit is open or closed. It is desirable to improve the ease-of-use of such a portable telephone. This is true for other kinds of information processing apparatuses besides the portable telephone.

There is a need for improve operability of the information processing apparatus.

### SUMMARY

The above stated need is met by an information processing apparatus comprising an open/close unit which is opened or closed by the user, a first user operation unit for receiving an input operation from the user when the open/close unit is closed, a second user operation unit for receiving an input operation from the user while the open/close unit is open, and a control unit for performing processing responding to the input operation which the first and second operation units received from the user. When opening of the open/close unit is detected after the control unit performed processing that responds to the first input operation is received from a user via the first user operation unit while the open/close unit is in the close state, then the control unit performs processing that responds to an second input operation, which can be the next processing, before receiving a an input operation subsequent to the first input operation from the user via the second user operation unit.

The above information processing apparatus is applicable to various kinds of apparatuses including, for example, a notebook personal computer, a portable telephone, a PHS (Personal Handy phone system), a PDA (Personal Digital Assistant), an electric home appliance, and the like.

The open/close unit may be of any types. For example, the open/close unit may be a second member (e.g. a housing or a member in the shape of a plate) which is openably and closeably mounted on the entire or part of a first member (e.g. a housing).

The second user operation unit may hide behind a predetermined member (for example, a member existing on top side) while the open/close unit is in the closed state, and may appear when the open/close unit is opened.

The information processing apparatus may comprise an open/close sensor for detecting opening and closing of the open/close unit. In that case, the control unit may determine whether the open/close unit is open or closed based on a signal inputted from the open/close sensor.

In a first example, the information processing apparatus may further comprise an input operation related storage area (e.g. a storage area on a memory) for storing various second input operations which are each associated with a plurality of kinds of the first input operations. In this case, when the opening state of the open/close unit is detected after the control unit performed processing responding to the first input operation, the control unit identifies the kind of the second input responding to the kind of the first input operation from the storage source to perform processing responding to the identified kind of second input operation.

In a second example, the information processing apparatus further comprises a telephone number storing area for storing one or a plurality of telephone numbers. When it is detected that the open/close unit is in an open state after it selected a telephone number from the one or the plurality of telephone numbers in response to the first input operation, the control unit issues a call using the selected telephone number.

In a third example, when it is detected that the open/close unit is in an open state after the control unit selected one received e-mail from one or a plurality of received e-mails, or after it selected an e-mail creation from among a plurality of e-mail related options in response to the first input operation, the control unit displays a screen of e-mail creation in a state of waiting information to be inputted (e.g. in a state of waiting an e-mail body to be inputted).

In the third example, the information processing apparatus further comprises, for example, an e-mail storage area for storing one or a plurality of received e-mails. In this situation, in response to an operation performed when the open/close unit is in the closed state, the control unit first displays a listing of the one or the plurality of received e-mails stored in the e-mail storage area on a first display screen (a screen that is visible on the outside while in the closed state). Then, the control unit, in response to the user's cursor operation, sets the cursor to some received e-mail. After that, when receiving an operation for determining a received e-mail with the cursor is set thereon as the first user input operation, the control unit displays an e-mail creation screen for inputting the body of the message of a reply e-mail to the received e-mail.

According to these examples, processing may be performed that responds to the second input operation without taking the trouble to perform the second input operation by performing the first input operation while the open/close unit is in the closed state before opening the open/close unit, thus making it possible to lighten the burden of input operation of the user.

Other objects, features and advantages of the invention will become apparent from the following description of the embodiments of the invention taken in conjunction with the accompanying drawings.

### BRIEF DESCRIPTION OF THE DRAWINGS

FIG. 1 is an exemplary front view of a sliding type portable telephone in an open state to which an information processing apparatus relating;

FIG. 2 is an exemplary view of the sliding type portable telephone of FIG. 1 in a closed state;

FIG. 3 a block diagram showing an exemplary configuration of a portable telephone 101;

FIG. 4 shows an exemplary configuration of an input operation estimation table 160;

FIG. 5 shows an exemplary flow of processing to be performed when the portable telephone extends after a called party is selected from an address book while the portable telephone is in a contracted state;

FIG. 6 shows an exemplary display screen at S2 of FIG. 5;

FIG. 7 shows an exemplary display screen at S5 of FIG. 5;

FIG. 8 shows an exemplary flow of processing to be performed when the portable telephone extends after a called party is selected from a outgoing call history or a incoming call history while the telephone is in a contracted state;

FIG. 9 shows an exemplary flow of processing to be performed when the portable telephone extends after a creation of a new e-mail is selected;

FIG. 10 shows an exemplary flow of processing to be performed when the portable telephone extends after a receipt box is selected, or displaying of detailed information on a received e-mail that is desired by the user is selected aftwerwards; and

FIG. 11 shows an exemplary flow of processing to be performed when the portable telephone extends after a transmission box is selected, or displaying of detailed information on the transmitted e-mail that is desired by the user is selected afterwards.

### DETAILED DESCRIPTION

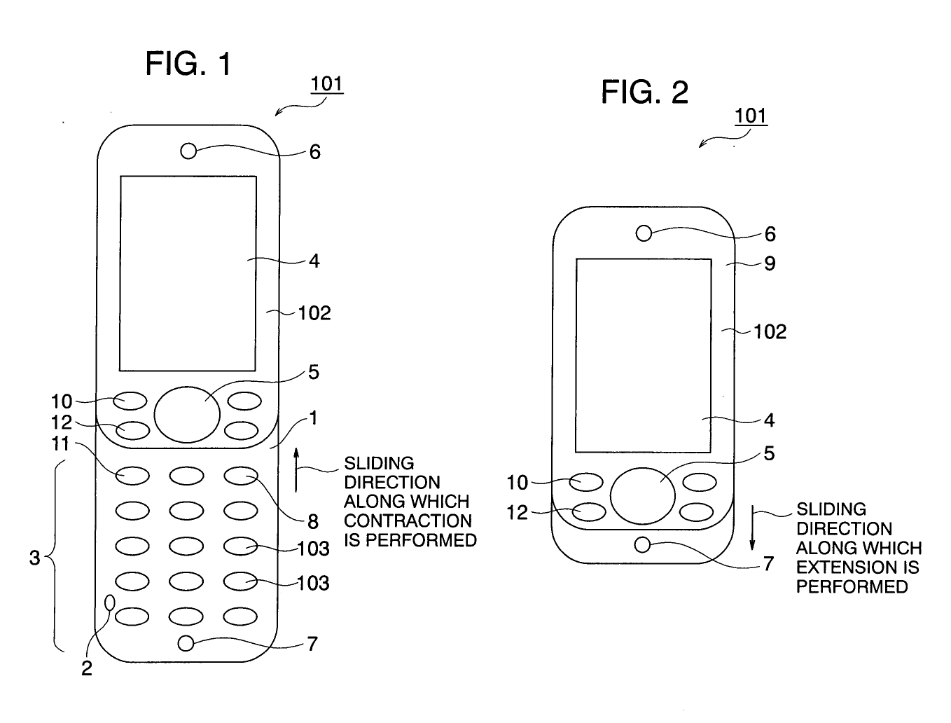

An information processing apparatus according to the present invention is applicable to a variety of information processing apparatuses having an open/close unit including a portable telephone, a PHS (Personal Handy phone System), a PDA (Personal Digital Assistant), a notebook personal computer, and the like. An example of the information processing will be described below taking a portable telephone that is slidably opened and closed (referred to as “a sliding type portable telephone” hereinafter) as an example of the information processing apparatus having an open/close unit. FIG. 1 is an exemplary front view of a sliding type portable telephone in an open state to which the information processing apparatus. FIG. 2 shows the sliding type telephone in a closed state. It should be noted that in the following description, opening of the sliding portable telephone is sometimes called as “extension” and closing as “contraction.”

The sliding type portable telephone (referred to as just a “portable telephone” hereinafter) 101 comprises an upperside housing 102, and a downside housing 1. The upperside housing 102 is mounted on the downside housing 1 such that they are relatively slidable to each other (in other words, extendably and contractibly). For example, as shown in FIG. 1, when the downside housing of the portable telephone 1 in an extended state finishes sliding towards the end of the upperside housing, the portable telephone is in a contracted state as shown in FIG. 2. Then, when the portable telephone in the contracted state finishes sliding towards the front end of the downside housing, the portable telephone is in the extended state as is shown in FIG. 1. In other words, in the example, the “contracted state” means a state of complete contraction ready to start an extending action, while the “extended state” means a state of complete extension after the completion of extending action and ready to start a contracting action.

The upperside housing 102 comprises: an information display unit (e.g. a liquid crystal display) 4; a voice output unit (e.g. a speaker) 6; a direction/Enter key 5 used for operations such as vertically and horizontally controlling a cursor or the like, determining an input, and the like; an address key 10 for calling up an undermentioned address book; and a mail key 12 for calling up a plurality of mail related options.

The underside housing 1 comprises: an contraction sensor 2 for sensing the extended state or contraction of the sliding type portable telephone 101; a plurality of input keys 3; and a voice output unit (e.g. a microphone) 7. The plurality of input keys 3 include, for example, a transmission key 11 to be operated when issuing a call, a clearing-out key 8 to be operated when terminating a call, and two or more character inputting keys 103 to be used when inputting characters and the like.

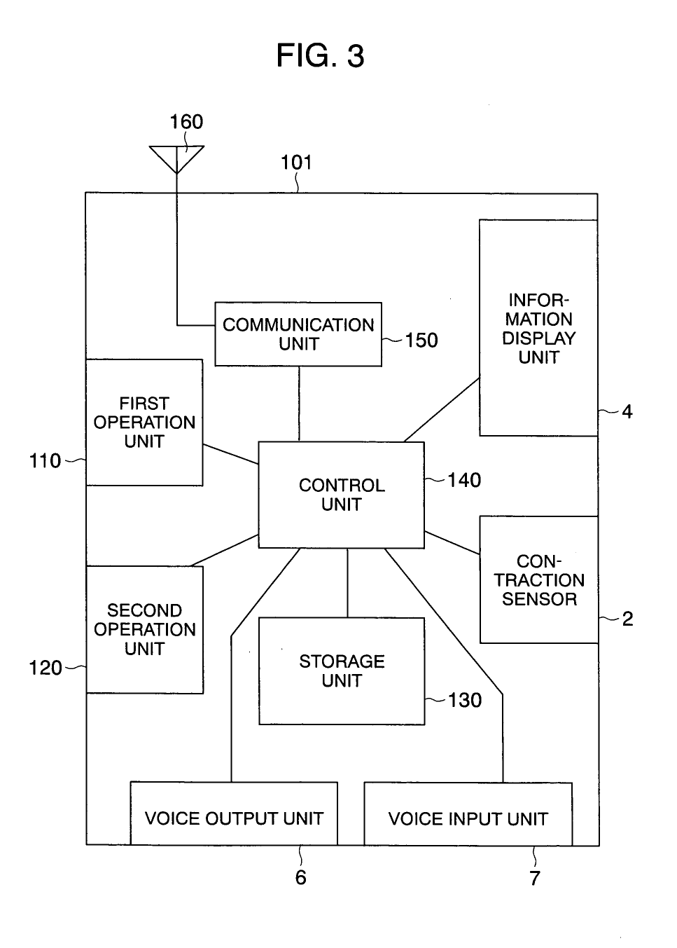

FIG. 3 is a block diagram showing a structure of a portable telephone 101.

The portable telephone 101 comprises: a wireless antenna 160 for transmitting an electric wave and receiving a signal; a communication unit 150 for performing communication via the wireless antenna 160; a first operation unit 110; a second operation unit 120; a storage unit 130; and a control unit 140, in addition to the aforementioned components.

The first operation unit 110 is operated by a user while the portable telephone is in a contracted state. The first operation unit 110 is, for example, provided on an upper surface of the upperside housing 102. Specifically, it includes: the direction/Enter key 5; an address key 10; and a mail key 12 as shown in FIGS. 1 and 2. As is evident from FIG. 2, while the portable telephone 101 is in the contracted state, the second operation unit 120 provided on the downside housing 1 hides behind the back face of the upperside housing 102, allowing the operation of only the first operation unit.

The second operation unit 120 is operated by the user while the portable telephone 101 is in the extended state. The operation unit 120 is, for example, provided on an upper surface of the underside housing 1. Specifically, it includes a plurality of input keys 3 as shown in FIGS. 1 and 2. As is evident from FIGS. 1 and 2, when the portable telephone 101 extends from the contracted state, the second operation unit 120 that was hiding behind the back face of the upperside housing 102 appears, allowing the operation of the second operation unit 120 in addition to the first operation unit 110.

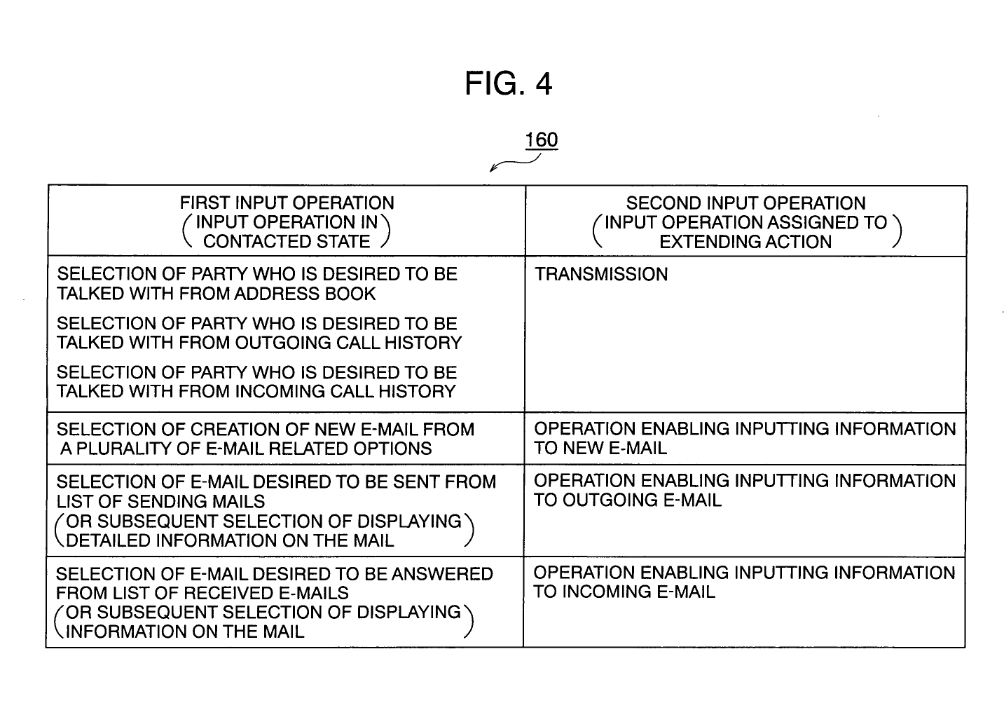

The storage unit 130 is a device capable of storing data. It is, for example, a memory or a hard disk. In the storage unit 130, for example, address book data (referred to just an “address book” below), in which address information on each of one or more called parties (for example, name, telephone number, and e-mail address) is recorded, one or more received e-mails that were received, one or more sending e-mails that will be transmitted, and the like, are stored. In the storage unit 130, for example, an outgoing call history, or a history record of telephone numbers of those who were called, and an incoming call history, or a history of telephone numbers of those who called, are also stored. Furthermore, an input operation estimation table 160 is also stored in the storage unit 130 as shown in FIG. 4.

A content of a plurality of kinds of the first input operations to be performed while in a contracted state, and a content of a plurality of kinds of the second input operations to be performed while in an extended state are registered in the input operation estimation table 160. In the input operation estimation table 160, the content of the kind of second input operations that are selected from the content of a plurality of kinds of second input operations are associated with the content of various first input operations. In other words, for each first input operation, input operations that are selected from a plurality of input operations that are operable after the first input operations are assigned to the extending action of the portable telephone 101 as shown by the input operation estimation table 160. Putting yet another way, the content of the second input operations that are associated with the content of the various first input operations is that of input operations estimated to be performed following the contents of the first input operations. A control unit 140, described later, performs processing following the association recorded in the input operation estimation table 160, which will be described in detail below.

The control unit 140 controls the operation of the communication unit 150, an output to the information display unit 4, an access to the storage unit 130, and at least one of outputs to the voice output unit 6 based on the operation content of the first operation unit 110 or the second operation unit 120, a detection signal from the contraction sensor 2, and at lease one of voice inputs from the voice inputting unit 7. More specifically, for example, when the extended state is determined from a detection signal from the contraction sensor 2 after the first input operation was performed at the first operation unit 110 while the telephone is in the contracted state, the control unit 140 performs processing that is appropriate to the first input operation and responds to the second input operation based on the content of the input operation estimation table 160 shown in FIG. 4 before the user uses the second operation unit 120 to perform the second input operation. Describing the foregoing more specifically with reference to FIG. 4, when the transition from the contracted state to the extended state is detected after the first input operation is performed, that is a selection of a party on the other end, who is desired to be talked with, from the address book, outgoing call history, or incoming call history, the control unit 140 performs processing that responds to an operation to issue a call (for example, by pushing the transmission key 11) using the telephone number of the selected party on the other end as processing responding to the second input operation subsequent to the first input operation. Moreover, when, for example, the transition from the contracted state to the extended state is detected after a first input operation is operated that is a selection of new creation from a plurality of e-mail related options, the control unit 140 performs processing that responds to an operation for enabling inputting information to the new e-mail (a determining operation using, for example, the direction/Enter key 5) as processing that responds to the second input operation subsequent to the first input operation. Furthermore, when the transition from the contracted state to the extended state is detected after a first input operation is performed that is a selection of an e-mail (an e-mail that was transmitted or will be transmitted), which is desired to be transmitted, from a list of sending e-mail (one or more sending mails), or a selection of displaying its detailed information, then the control unit 140 also performs processing that responds to the operation for enabling inputting information to the e-mail that will be sent (for example, a determining operation using the direction/Enter key 5). Moreover, when the transition from the contracted state to the extended state is detected after a first input operation is performed that is a selection of an e-mail, of which reply e-mail is desired to be sent, from a list of received e-mails (one or more incoming e-mails), or a selection of displaying detailed information on the e-mail, the control unit 140 also performs processing responding to an operation for enabling inputting information to the reply e-mail (for example, a determining operation using the direction/Enter key 5) as processing responding to the second input operation subsequent to the first input operation.

A flow of several processing to be performed in the present embodiment will be described below.

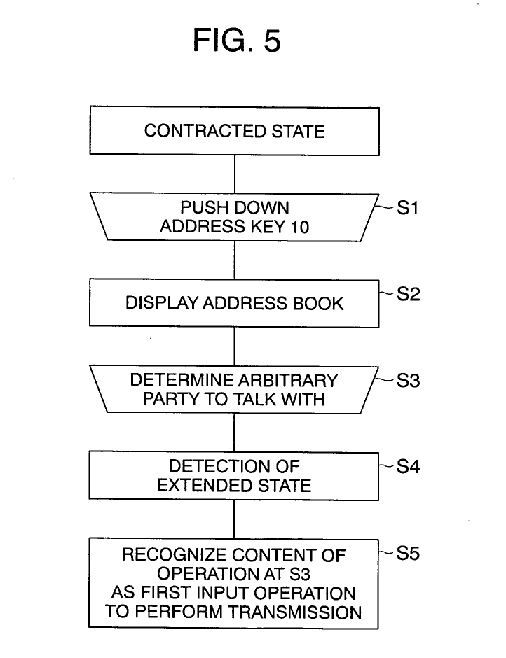

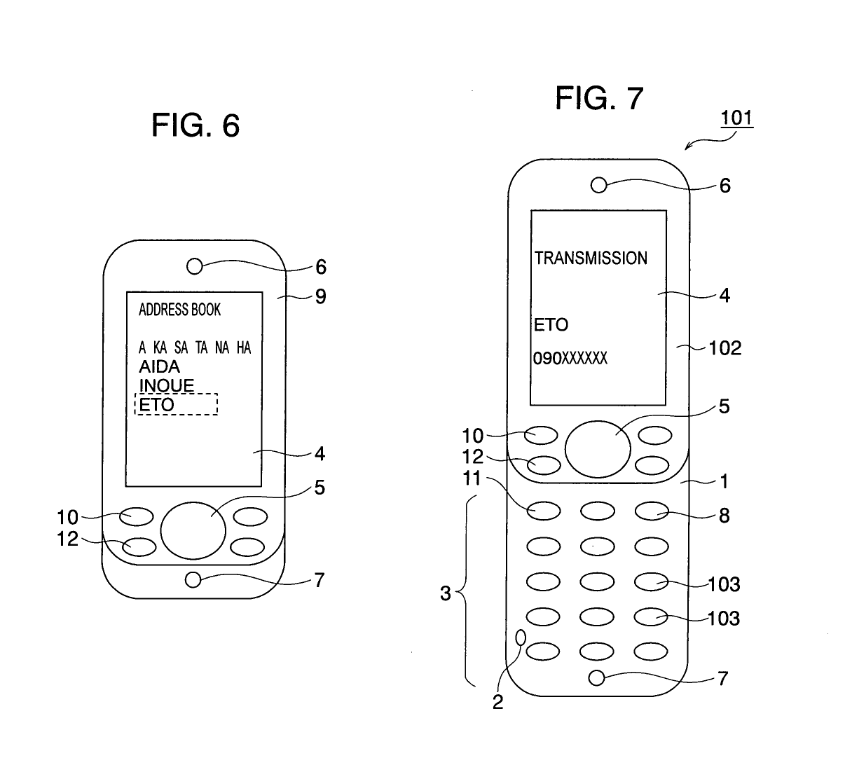

FIG. 5 shows a flow of processing to be performed while in the extended state after a party on the other end is selected from the address book. It should be noted that FIGS. 6 and 7 are used as required in the following description.

When a content of the first input operation that was performed using the first operation 110 while in the contracted state is to push down an address key 10 (step S1), the control unit 140 reads out the address book from a storage unit 130 for displaying on the display unit 4 (S2) as illustrated in FIG. 6.

Then, when the extended state (or a start of the extension after the completion of contraction) is detected (S4) after the direction/Enter key 5 was operated and an arbitrary party to talk with was selected and determined (S3) from the address book, with no other input operations being performed afterward, the control unit 140 recognizes the input operation immediately before the detection (specifically, the input operation received at S3) as the first input operation. Then, the control unit 140 searches the input operation estimation table 160 for the content of a second input operation corresponding to the content of the first input operation to perform processing responding to the searched second input operation, or to issue a call using the telephone number of the party on the other end determined at S3 as illustrated in FIG. 7 (S5).

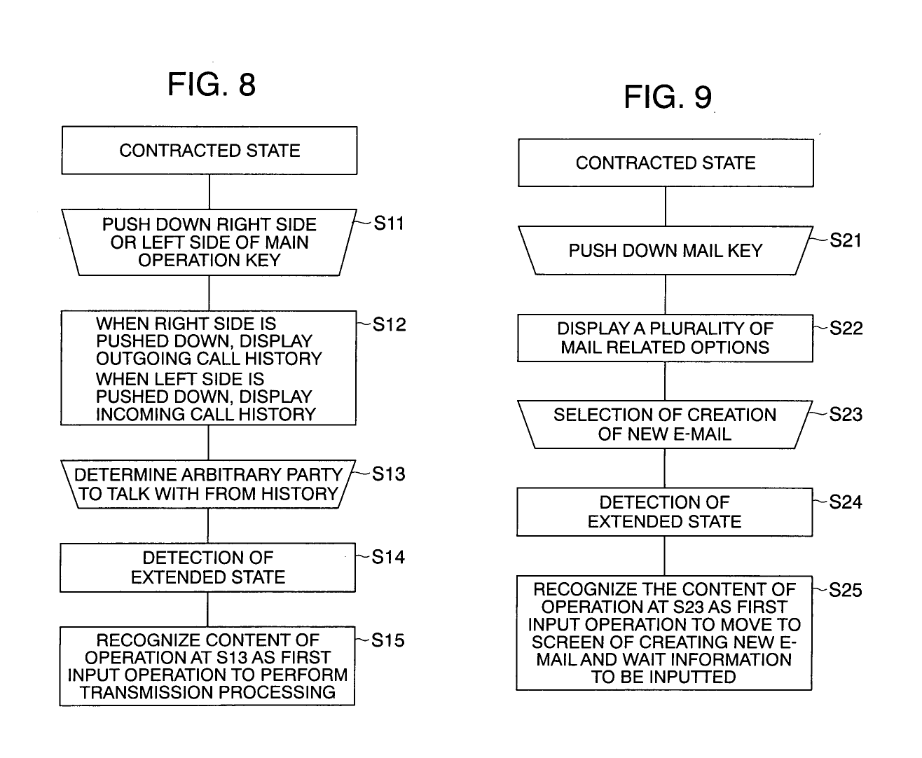

FIG. 8 shows a flow of processing to be performed while in the extended state after a party of other end is selected from the outgoing call history or incoming call history.

When the content of the first input operation while the portable telephone is in the contracted state is pushing down the right side or left side of the direction/Enter key 5 (S11), the control unit 140 reads out the outgoing call history or the incoming call history for displaying on the information display unit 4 (S12).

After that, when the extended state is detected (S14) after an arbitrary party to talk with is selected and determined by pushing down the direction/Enter key 5 (S13) with no other input operation being performed afterwards, the control unit 140 recognizes the input operation immediately before the detection (or an input operation received at S13 in FIG. 8) as the first input operation. Then, the control unit 140 searches the input operation estimation table 160 for the content of the second input operation corresponding to the content of the first input operation to perform processing responding to the searched second input operation, or to issue a call using the telephone number of the party to talk with that is determined at S13 (S15).

FIG. 9 shows a flow of processing to be performed when the portable telephone is in the extended state after the creation of a new e-mail is selected.

When the content of the first input operation that was performed using the first operation unit 110 is pushing down the mail key 12 (S21), the control unit 140 displays a list of a plurality of e-mail options (S22).

Then, when it is detected that the portable telephone is in the extended state (S24) after the creation of a new e-mail is selected (S23) from a plurality e-mail options by pushing down the direction/Enter key 5 with no other input operation being performed afterwards, the control unit 140 recognizes the input operation immediately before the detection of the extended state (or an input operation received at S23) as the first input operation. Then, the control unit 140 searches the input operation estimation table 160 for the content of the second input operation corresponding to the content of the first input operation to perform processing responding to the searched second input operation, or to move to a screen of creating a new e-mail, and wait information to be inputted (in other words, to display a screen of the creation of a new e-mail that is in a state of waiting information to be inputted) (S25).

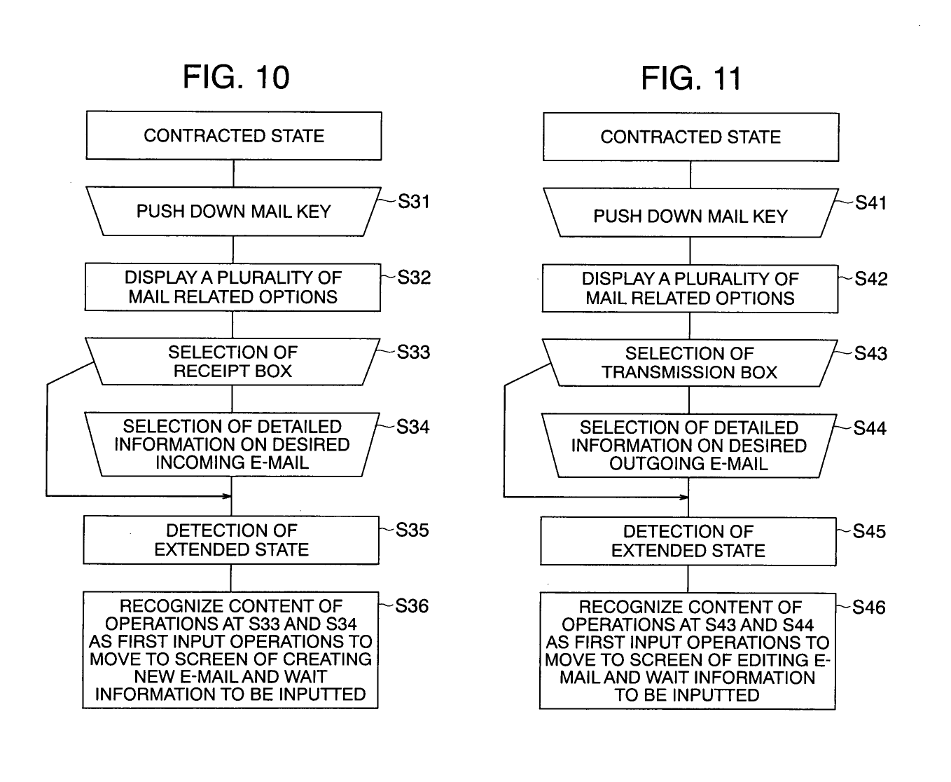

FIG. 10 shows a flow of processing to be performed when the portable telephone is in the extended state after a receipt box is selected, or displaying detailed information of a received e-mail which the user desires is selected afterwards.

When the content of the first input operation that was performed using the first operation unit 110 while the portable telephone is in the contracted state is pushing down the mail key 12 (S31), the control unit 140 displays a list of a plurality of e-mail options (S32).

After that, when the extended state is detected (S35) after the direction/Enter key 5 is operated and displaying of the receipt box (a list of incoming e-mails) is selected from among a plurality of e-mail options (S33), or displaying detailed information of the e-mail in the receipt box that is desired by the user is selected (S34) followed by no other input operation, the control unit 140 recognizes the input operation immediately before the detection (or the input operations received at S33 or S34) as the first input operation. Then the control unit 140 searches the input operation estimation table 160 for the content of the second input operation corresponding to the content of the first input operation to perform an operation corresponding to the searched second input operation, or to move to screen of creating a reply e-mail and wait information to be inputted (in other words, to display a screen of creating a reply e-mail in a state of waiting information to be inputted) (S36).

FIG. 11 shows a flow of processing to be performed when the portable telephone is in the extended state after a sending box is selected, or the displaying of detailed information of the e-mail desired by the user is selected afterwards.

When the content of the first input operation that was performed using the first operation unit 110 while the portable telephone is in the contracted state is pushing down the mail key 12 (S41), the control unit 140 displays a list of a plurality of e-mail options (S42).

Afterwards, when the extended state of the portable telephone is detected (S45) after the direction/Enter key 5 is operated, displaying of the sending box (a list of outgoing e-mails) is selected from among a plurality of e-mail options (S43), or displaying of detailed information of the e-mail in the sending box desired by the user is selected (S44) followed by no other input operation, the control unit 140 recognizes the input operation immediately before the detection (or the input operations performed at S43 or S44) as the first input operation. Then the control unit 140 searches the input operation estimation table 160 for the content of the second input operation corresponding to the content of the first input operation to perform an operation responding to the searched second input operation, or to move to a screen of editing an e-mail and wait information to be inputted (in other words, to display a screen of editing an e-mail in a state of waiting information to be inputted) (S46).

According to the examples described above, performing the first input operations while the portable telephone 101 is in the contracted state before being extended would enable operations responding to the second input operations without taking trouble to perform the second input operations. This lightens the burden of input operation of the user and improves operability.

The examples of the present invention have been described in the above. It should be recognized that the above description is just for explaining the present invention, and not intended to limit the present invention to the scope of the examples. Numerous variations and/or modifications may be made to the invention without departing from the spirit or scope of the present invention.

1. An information processing apparatus, said apparatus comprising:
an open/close unit which is opened or closed by a user;
a first user operation unit that receives input operations from the user while the open/close unit is in a closed state;
a second user operation unit that receives input operations from the user while the open/close unit is in an open state;
a control unit that performs processing that responds to input operations which said first user input operation unit and said second user operation user unit received from the user; wherein
when opening of said open/close unit is detected after processing is performed that responds to a first input operation that was received from the user via said first user operation unit while said open/close unit is in the closed state, said control unit performs processing that responds to a second input operation, which can be a next input operation, before receiving said next input operation subsequent to said first input operation from the user via said second user operation unit.

2. The information processing apparatus according to claim 1, said apparatus further comprising an input operation related storage area for storing various second input operations associated with each of a plurality of kinds of first input operations, wherein:
when the opening of said open/close unit is detected after the processing is performed that responds to said first input operation, said control unit identifies the kind of second input operation that corresponds to the kind of said first input operation, and performs processing that responds to the kind of said identified second input operation.

3. The information processing apparatus according to claim 1, said apparatus further comprising a telephone number storage area for storing one or a plurality of telephone numbers, wherein
when the opening of said open/close unit is detected after one telephone number is selected from the one or the plurality of telephone numbers that are stored in said telephone number storage area in response to said first input operation, said control unit issues a call using said selected telephone number.

4. The information processing apparatus according to claim 1, wherein when the opening of said open/close unit is detected after one received e-mail is selected from one or a plurality of received e-mails, or an e-mail creation is selected from a plurality of e-mail related options in response to said first input operation, said control unit displays an e-mail creation screen that is in a state of waiting information to be inputted.
